(19) United States
(12) Patent Application Publication
(10) Pub. No.: US 2025/0136374 A1
(43) Pub. Date: May 1, 2025

(54) TRANSPORT VEHICLE AND TRANSPORT SYSTEM INCLUDING THE SAME

(71) Applicant: SAMSUNG ELECTRONICS CO., LTD., Suwon-si (KR)

(72) Inventors: Seong Sil JEONG, Suwon-si (KR); Youn Gon Oh, Suwon-si (KR); Sang Hyuk Park, Suwon-si (KR)

(73) Assignee: SAMSUNG ELECTRONICS CO., LTD., Suwon-si (KR)

(21) Appl. No.: 18/608,425

(22) Filed: Mar. 18, 2024

(30) Foreign Application Priority Data
Oct. 27, 2023 (KR) 10-2023-0145613

(51) Int. Cl. B65G 1/04

(52) U.S. Cl. CPC B65G 1/0464

(57) ABSTRACT

A transport vehicle includes: a frame having an internal area; a driver on top of the frame, the driver being configured to travel along a rail; a support structure in the internal area, the support structure being configured to seat, thereon, a drone configured to transport an article; and a controller configured to control an operation of at least one of the driver and the support structure.

### CROSS-REFERENCE TO RELATED APPLICATION

This application is based on and claims priority under 35 U.S.C. § 119 to Korean Patent Application No. 10-2023-0145613, filed on Oct. 27, 2023, in the Korean Intellectual Property Office, the disclosure of which is incorporated by reference herein in its entirety.

### BACKGROUND

### 1. Field

The disclosure relate to a transport vehicle and a transport system including the transport vehicle.

### 2. Description of Related Art

In a semiconductor manufacturing process, a substrate is stored in a container such as a front opening unified pod (FOUP), and is moved by a transport vehicle, such as an overhead hoist transport (OHT). When the transport vehicle transports the container to a load port of a process facility, the process facility opens the container, takes out the substrate, and proceeds with the manufacturing process thereon.

### SUMMARY

In one example, a plurality of transport vehicles may move along the same rail. When the transport vehicle at a front position is loading or unloading an article, the transport vehicle next thereto should wait until the transport vehicle at the front position finishes the loading or unloading. Thus, congestion of the plurality of transport vehicles may occur.

Therefore, in order to reduce a congestion time of the transport vehicle, the loading and unloading time of the transport vehicle need to be reduced or minimized. However, in the transport vehicle, a hand that handles the article and a hoist that raises and lowers the hand are connected to each other via a belt. When the belt is quickly released to reduce the loading and unloading time, shaking thereof becomes significantly severe. When the shaking becomes severe, the article cannot be loaded or unloaded reliably.

Additionally, in order for the transport vehicle to place and pick up the article to and from a correct position, the transport vehicle needs to stop at the correct position. A tag is installed on the rail to indicate the correct position, and the transport vehicle recognizes the tag and stops at the correct position. However, a position of the tag is adjusted as needed. To this end, an operator takes a risk of performing a task of adjusting the tag's position at a height of approximately 5 m from a floor.

Provided is a transport vehicle that may transport an article quickly and reliably. Provided is a transport system that may transport an article quickly and reliably.

Technical aspects of the disclosure are not limited to the above-mentioned purpose. Other technical aspects of the disclosure, which are not mentioned herein, may be understood based on following descriptions, and may be more clearly understood based on embodiments of the disclosure. Further, it will be easily understood that the purposes and advantages according to the disclosure may be realized using means shown in the claims or combinations thereof.

According to an aspect of the disclosure, a transport vehicle includes: a frame having an internal area; a driver on top of the frame, the driver being configured to travel along a rail; a support structure in the internal area, the support structure being configured to seat a drone for transporting an article; and a controller configured to control an operation of at least one of the driver and the support structure.

According to an aspect of the disclosure, a transport vehicle includes: a frame having an internal area; a driver on top of the frame, the driver being configured to move along a rail; a support structure in the internal area, the support structure being configured to seat a drone configured to transport an article; and an anti-drop member at the support structure, the anti-drop member being configured to prevent the drone seated on the support structure from falling down; and a wireless power supply in the frame, the wireless power supply being configured to supply power to the drone during at least a portion of a period during which the drone is seated on the support structure, wherein the drone includes: a body; a wing assembly connected to the body, the wing assembly being configured to generate a lift force to fly the drone; a gripper connected to the body, the gripper being configured to grip the article; a leg connected to the body, the leg being configured to support the body when the drone is seated on the support structure; a wireless charging pad installed on the wing assembly, the wireless charging pad being configured to receive the power from the wireless power supply; a battery connected to the wireless charging pad, the battery being configured to store the power received from the wireless power supply; and a reader (e.g., an image sensor or a camera) on the leg, the reader being configured to read an information tag on a load port or the support structure.

According to an aspect of the disclosure, a transport system includes: a rail; a first transport vehicle configured to move along the rail; and a drone configured to be seated on the first transport vehicle, move to a first point, be removed from the first transport vehicle at the first point, and fly to a second point, and pick up an article at the second point, wherein the first transport vehicle includes: a frame having an internal area; a driver on top of the frame, the driver being configured to move along the rail; a support structure in the internal area, the support structure being configured to seat the drone thereon; and a controller configured to control an operation of at least one of the driver or the support structure.

Specific details of other embodiments are included in the detailed descriptions and drawings.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a diagram for illustrating a transport system, according to one or more embodiments of the disclosure;

FIG. 2 is a block diagram for illustrating a transport vehicle, according to one or more embodiments of the disclosure;

FIG. 3 is a perspective view for illustrating an example configuration of the transport vehicle in FIG. 2, according to one or more embodiments of the disclosure;

FIG. 4 is a diagram for illustrating a support structure in FIG. 3, according to one or more embodiments of the disclosure;

FIG. 5 is a block diagram for illustrating a drone in FIG. 2, according to one or more embodiments of the disclosure;

FIG. 6 is a perspective view for illustrating an example configuration of the drone in FIG. 5, according to one or more embodiments of the disclosure;

FIG. 7 is an exploded perspective view for illustrating an example configuration of the drone in FIG. 5, according to one or more embodiments of the disclosure;

FIG. 8 is a diagram for illustrating a gripper of the drone as shown in FIG. 7, according to one or more embodiments of the disclosure;

FIG. 9 is a block diagram for illustrating a transport system, according to one or more embodiments of the disclosure;

FIG. 10 is a flowchart for illustrating a method for operating a transport system operates, according to one or more embodiments of the disclosure;

FIG. 11 to FIG. 17 are diagrams of intermediate steps of the method of FIG. 10, according to one or more embodiments of the disclosure;

FIG. 18 is a diagram for illustrating a method for operating a transport system, according to one or more embodiments of the disclosure; and

FIGS. 19A and 19B are a flowchart for illustrating a method for operating a transport system, according to one or more embodiments of the disclosure.

### DETAILED DESCRIPTIONS

Hereinafter, embodiments of the disclosure are described in detail with reference to the attached drawings. The same reference numerals are used for the same components in the drawings, and duplicate descriptions thereof are omitted.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

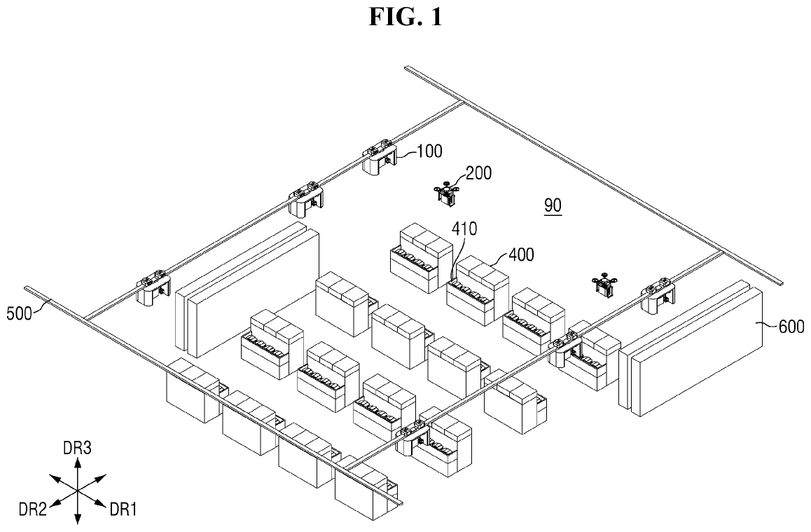

FIG. 1 is a diagram for illustrating a transport system according to one or more embodiments.

Referring to FIG. 1, within a bay 90 of a semiconductor manufacturing plant FAB, a plurality of manufacturing facilities 400 and at least one stocker 600 may be disposed.

As shown, the plurality of manufacturing facilities 400 may be arranged in a row along a first direction DR1. A plurality of rows may be arranged side by side along a second direction DR2. In an example, it is shown that four manufacturing facilities 400 constitute one row and four rows are arranged side by side. However, embodiments of the disclosure are not limited thereto.

Furthermore, at least one stocker 600 is disposed around the plurality of manufacturing facilities 400. The stocker 600 includes a plurality of storage areas for storing therein articles.

A rail 500 is installed on a ceiling of the semiconductor manufacturing plant FAB. That is, the rail 500 is installed so as to be spaced apart from a floor of the semiconductor manufacturing factory in a third direction DR3. A transport vehicle 100 may run along the rail 500 in a ceiling area of the semiconductor manufacturing plant. In this regard, the rail 500 may not be installed within the bay 90, but may be installed around the bay 90. For example, when the plurality of manufacturing facilities 400 are arranged in a row while a passage is defined therebetween, the rail 500 is not installed in the passage. Alternatively, the rail 500 is not formed directly on top of a load port 410 of each of the plurality of manufacturing facilities 400, that is, does not overlap the load port 410 of each of the plurality of manufacturing facilities 400 in the third direction DR3.

A cable that supplies power is installed in the rail 500. The transport vehicle 100 may operate upon receiving the power through the cable. In an embodiment, a driver of the transport vehicle 100 may operate using the power provided through the cable, and a drone 200 mounted on the transport vehicle 100 may also operate upon receiving the power.

In an embodiment, the transport vehicle 100 carries the drone 200 thereon and moves the drone 200 to a first point. The first point is, for example, a point not within the bay 90 but around the bay 90. At the first point, the drone 200, which is removed from the transport vehicle 100, flies to a second point. The second point may be, for example, the load port 410 in the manufacturing facility 400, or the storage area (or a shelf) in the stocker 600. At the second point, the drone 200 picks up an article or puts the article down.

In this way, the drone 200 flies to the load port 410 of the manufacturing facility 400 and picks up the article from the load port 410. Thus, the rail 500 does not need to be installed inside the bay 90 (for example, the rail 500 does not need to be installed directly on top of the load port 410). Furthermore, for accurate loading and unloading, a tag indicating a position where the transport vehicle 100 should stop (that is, a position tag) may not be installed on the rail 500.

Furthermore, because the drone 200 flies to the storage area of stocker 600 and picks up the article therefrom, a separate robot for loading and unloading of the vehicle (for example, a crane to handle the article) may not be installed in the stocker 600.

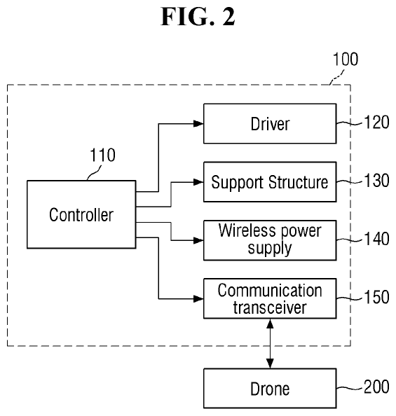

Hereinafter, using FIG. 2 to FIG. 7, a configuration of each of the transport vehicle 100 and the drone 200 riding on the transport vehicle 100, according to one or more embodiments, will be described.

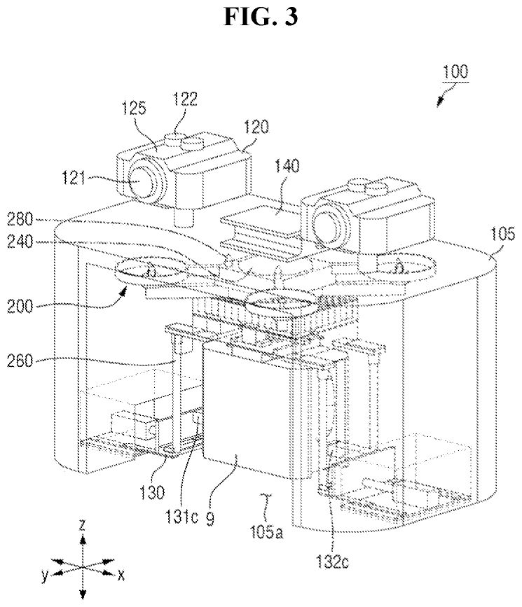

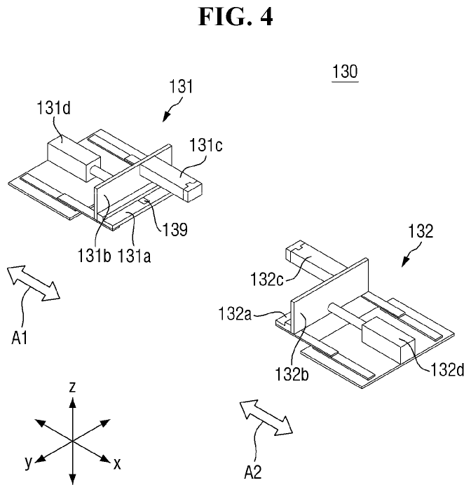

FIG. 2 is a block diagram for illustrating the transport vehicle 100 according to one or more embodiments. FIG. 3 is a perspective view for illustrating an example configuration of the transport vehicle 100 in FIG. 2. FIG. 4 is a diagram for illustrating a support structure in FIG. 3.

First, referring to FIG. 2 and FIG. 3, the transport vehicle 100 according to one or more embodiments include a controller 110, a frame 105, a driver 120, a support structure 130, a wireless power supply 140, and a communication transceiver 150. The controller 110 may control an operation of at least one of the driver 120, the support structure 130, the wireless power supply 140, and the communication transceiver 150.

The controller 110 may correspond to at least one processor that includes or corresponds to circuitry like a central processing unit (CPU), a microprocessor unit (MPU), an application processor (AP), a coprocessor (CP), a system-on-chip (SoC), or an integrated circuit (IC).

The frame 105 constitutes a basic framework of the transport vehicle 100 and provides an internal area 105a. The support structure 130 may be installed in the internal area 105a, and the drone 200 may be mounted on the support structure 130.

The driver 120 is installed on top of the frame 105 and is configured to travel along the rail 500. The driver 120 may include a motor 125 that provides power, a driving wheel 121 that rotates and moves along the rail 500, and a steering wheel 122 that changes a driving direction.

In one example, a coil and a steel plate may be installed in the frame 105, and may receive electrical power from the cable installed on the rail 500 in an electromagnetic induction scheme. Furthermore, the wireless power supply 140 may be installed in the frame 105, and may transmit received power to the drone 200. That is, the wireless power supply 140 may supply the power to the drone 200 at least when the drone 200 is seated on the transport vehicle 100.

The communication transceiver 150 may be installed in the frame 105. The transport vehicle 100 may be configured to communicate with the drone 200 or a higher-level control system via the communication transceiver 150. For example, the transport vehicle 100 may receive a transport command from a higher-level control system via the communication transceiver 150 and set a destination or a route. Furthermore, the transport vehicle 100 may be configured to communicate with the drone 200 via the communication transceiver 150 to exchange information with each other.

The support structure 130 is installed in the internal area 105a of the frame 105, and the drone 200 is seated on the support structure 130.

As shown in FIG. 4, the support structure 130 includes a first support structure 131 and a second support structure 132 arranged to face each other.

The first support structure 131 includes a first support plate 131a and a first driving component 131d that moves the first support plate 131a forward or backward along an x-direction (“A1” in FIG. 4).

The second support structure 132 includes a second support plate 132a and a second driving component 132d which moves the second support plate 132a forward or backward along the x-direction (“A2” in FIG. 4).

The first support plate 131a and the second support plate 132a are arranged to face each other. An area between the first support plate 131a and the second support plate 132a may be adjusted under an operation of the first and second driving components 131d and 132d.

The drone 200 is seated on the first support plate 131a and the second support plate 132a. A flight motor of the drone 200 may not operate while the transport vehicle 100 is moving.

Further, an anti-drop member may be disposed in each of the first support structure 131 and the second support structure 132. The anti-drop member may be configured to prevent the drone 200 from falling from the transport vehicle 100 even when the drone 200 does not operate the flight motor.

Specifically, the anti-drop member (installed in the first support structure 131) may include a first rod 131c connected to the first support plate 131a and may be configured to protrude beyond a first edge of the first support plate 131a. The first rod 131c may be installed at a first vertical plate 131b connected to the first support plate 131a. The anti-drop member may include or correspond to the first vertical plate 131b and/or the first rod 131c. However, embodiments of disclosure are not limited thereto.

Furthermore, the anti-drop member installed in the second support structure 132 may include a second rod 132c connected to the second support plate 132a and configured to protrude beyond a second edge of the second support plate 132a. The second rod 132c may be installed at a second vertical plate 132b connected to the second support plate 132a. The anti-drop member may include or correspond to the second vertical plate 132b and/or the second rod 132c. However, embodiments of the disclosure are not limited thereto.

Each of the anti-drop members (e.g., the first rod 131c and/or the second rod 132c) may move forward or backward along the x-direction together with each of the first support plate 131a and the second support plate 132a under the operation of each of the first driving component 131d and the second driving component 132d. As shown in FIG. 3, the anti-drop members (e.g., the first rod 131c and/or the second rod 132c) may secure the drone 200 and/or an article 9.

In one example, as shown in FIG. 4, an information tag 139 may be installed on the first support plate 131a and/or the second support plate 132a. The information tag 139 may be, for example, a QR code. However, embodiments of the disclosure are not limited thereto. A reader installed in the drone 200 may read the information tag 139 to obtain unit-specific information of the transport vehicle 100. Examples of the reader are an image sensor, a camera, and a QR code reader (an optical device that can read QR codes).

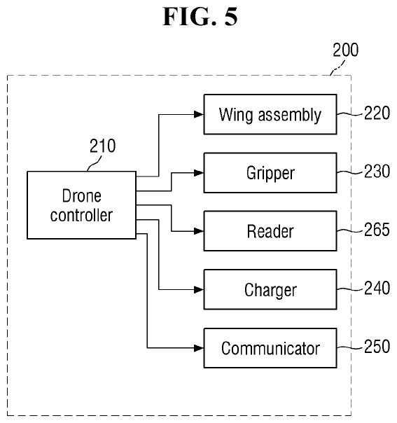

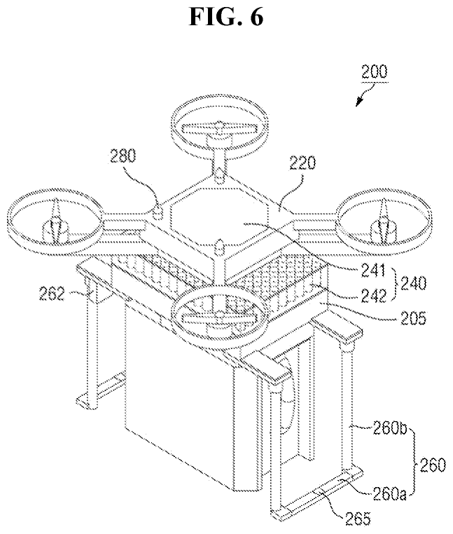

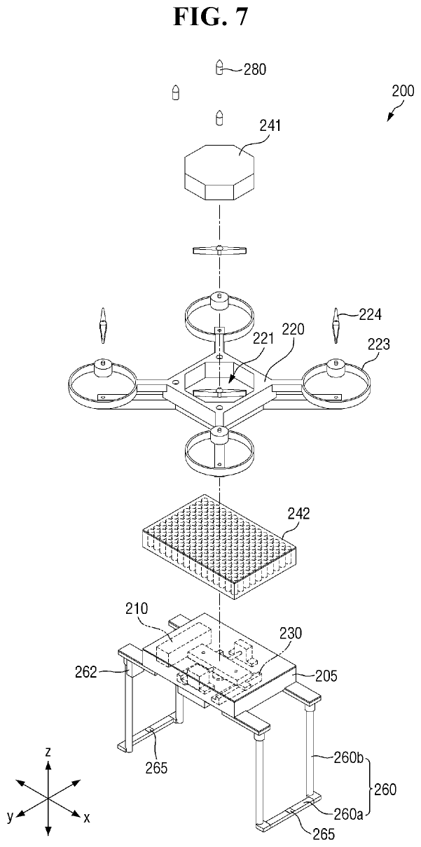

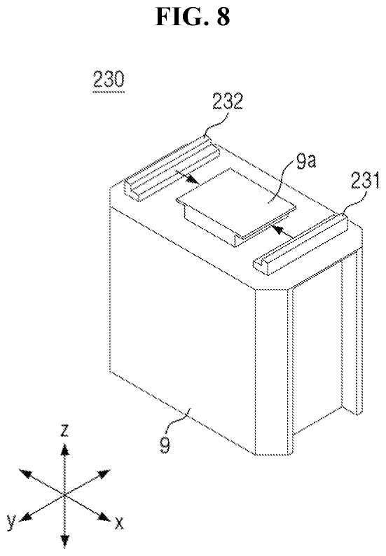

FIG. 5 is a block diagram for illustrating the drone 200 in FIG. 2. FIG. 6 is a perspective view for illustrating an example configuration of the drone 200 in FIG. 5. FIG. 7 is an exploded perspective view for illustrating an example configuration of the drone 200 in FIG. 5. FIG. 8 is a diagram for illustrating a gripper of the drone 200 as shown in FIG. 7.

First, referring to FIG. 5 to FIG. 7, the drone 200 according to one or more embodiments includes a drone controller 210, a body 205, a wing assembly 220, a gripper 230, a reader 265, a charger 240, a communicator 250, a leg 260, and a position pin 280, etc. The drone controller 210 may control an operation of at least one of the wing assembly 220, the gripper 230, the reader 265, the charger 240, and the communicator 250. The drone controller 210 may correspond to at least one processor that includes or corresponds to circuitry like a central processing unit (CPU), a microprocessor unit (MPU), an application processor (AP), a coprocessor (CP), a system-on-chip (SoC), or an integrated circuit (IC).

The wing assembly 220 is connected to the body 205 and generates a lift force to fly the drone 200. The wing assembly 220 may include a plurality of propellers 224 (for example, four propellers), and a motor that rotates the plurality of propellers 224. However, embodiments of the disclosure are not limited thereto. The drone controller 210 controls a flight speed and a travel direction under control of a rotation speed of the motor, and achieves a posture balance of the drone 200 by rotating diagonally opposite motors in the same direction. Optionally, the wing assembly 220 may further include a cover 223 surrounding the propeller 224 to protect the propeller 224.

The gripper 230 is connected to the body 205 and is configured to grip the article 9.

As shown in FIG. 7 and FIG. 8, the gripper 230 may grip a handle 9a disposed at a top of the article 9 (for example, a front opening unified pod (FOUP)). The gripper 230 may include, for example, a first gripping bar 231 and a second gripping bar 232. The first gripping bar 231 and the second gripping bar 232 may be configured to move forward or backward in a direction parallel to the moving direction of the first support structure 131 and the second support structure 132 of the transport vehicle 100, for example, in the x-direction.

Referring again to FIG. 5 to FIG. 7, the leg 260 is connected to the body 205 and is configured to support the body 205 and other components when the drone 200 is seated on the transport device. The leg 260 includes a first part 260b which extends in an elongate manner in a z-direction, and a second part 260a which is connected to the first part 260b and extend in a y-direction. When the drone 200 is seated on the transport vehicle 100, the second part 260a may directly contact the first support plate 131a and the second support plate 132a of the transport vehicle 100.

The reader 265 may be installed on the leg 260. For example, the reader 265 may be installed on the second part 260a of the leg 260. When the drone 200 lands on the transport vehicle 100, the reader 265 reads the information tag 139 (in FIG. 4) installed on the support structure 130 of the transport vehicle 100. Alternatively, when the drone 200 lands on the manufacturing facility, the reader 265 reads the information tag installed on the manufacturing facility.

Furthermore, a parallel input output (PIO) sensor 262 may be installed on the leg 260. The PIO sensor 262 may be installed on the first part 260b of the leg 260. When the drone 200 lands on the manufacturing facility, the PIO sensor 262 communicates with a PIO sensor installed on the manufacturing facility. Through the communication, the two PIO sensors may exchange article information with each other.

The charger 240 receives power from the transport vehicle 100. For example, the charger 240 receives the power wirelessly from the wireless power supply (refer to 140 in FIGS. 2 and 3) installed in the frame 105 of the transport vehicle 100.

The charger 240 may include a wireless charging pad 241 (configured to receive the power from the wireless power supply 140 of the transport vehicle 100) and a battery 242 (that is electrically connected to the wireless charging pad 241 and stores the supplied power therein).

The wireless charging pad 241 may be installed in the groove 221 where a frame of the wing assembly 220 is installed. However, embodiments of the disclosure are not limited thereto. As shown, the wireless charging pad 241 may have a polygonal shape, for example, an octagon. However, embodiments of the disclosure are not limited thereto.

The drone 200 communicates with the transport vehicle 100 or an upper-level control system through the communicator 250. For example, the drone 200 may set a destination or a route upon receiving a transport command from the upper-level control system via the communicator 250. Furthermore, the drone 200 may communicate with the transport vehicle 100 via the communicator 250 to exchange information with each other.

The position pin 280 may be installed on an upper surface of the wing assembly 220. However, embodiments of the disclosure are not limited thereto.

In an embodiment, a position hole may be installed inside the frame 105 (in FIG. 3) to determine a position of the drone 200 when the drone 200 docks at the frame. The position pin 280 of the drone 200 is engaged with the position hole to determine the position of the drone 200 when the drone docks at the frame 105 of the transport vehicle 100. In other words, the position pin 280 and the position hole serve to guide the drone 200 so that the drone may land at correct position in the internal area 105a of the transport vehicle 100.

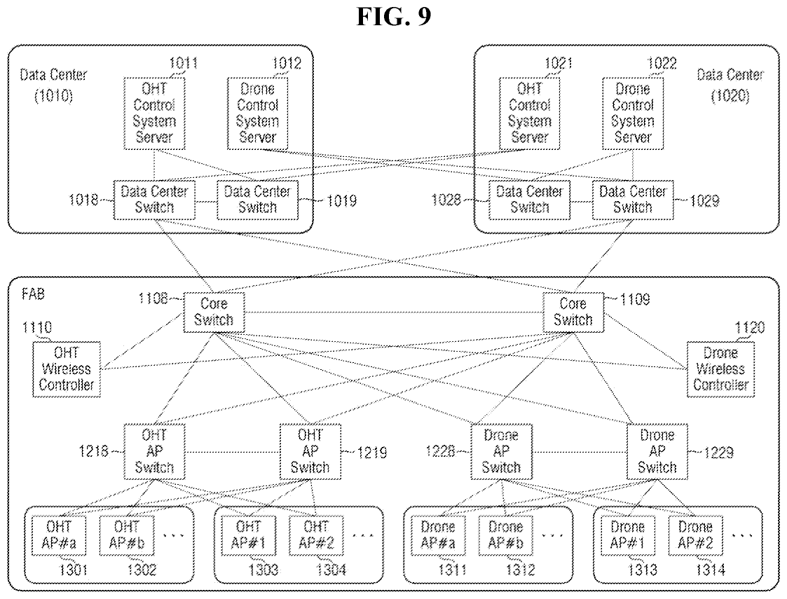

FIG. 9 is a block diagram for illustrating a transport system according to one or more embodiments. Specifically, FIG. 9 illustrates a configuration of a wireless network system for controlling the plurality of transport vehicles and the plurality of drones.

Referring to FIG. 9, a first wireless network system for controlling the plurality of transport vehicles is configured in a dual manner for stable control. Likewise, a second wireless network system for controlling the plurality of drones is configured in a dual manner for stable control. The first wireless network system and the second wireless network system use different bands and different channels. Furthermore, an access point (AP) for the transport vehicle and an AP for the drone 200 may be installed separately. Furthermore, network switches may also be divided into a network switch for the transport vehicle 100 and a network switch for the drone 200. Thus, the transport vehicle 100 and the drone 200 may be controlled separately via the separate network systems in a local network. In a data center, a server for the transport vehicle 100 and a server for the drone 200 may be installed separately. However, the network for the transport vehicle 100 and the network for the drone 200 may be connected to each other at a higher layer.

The wireless network may be configured as shown in FIG. 9.

Specifically, a first data center 1010 includes a transport vehicle control system server 1011, a drone control system server 1012, and a plurality of data center switches 1018 and 1019.

A second data center 1020 includes a transport vehicle control system server 1021, a drone control system server 1022, and a plurality of data center switches 1028 and 1029.

The semiconductor manufacturing factory FAB includes a transport vehicle wireless controller 1110, a drone wireless controller 1120, a plurality of core switches 1108 and 1109, a plurality of AP switches 1218, 1219, 1228, and 1229, a plurality of transport vehicles 1301, 1302, 1303, and 1304, and a plurality of drones 1311, 1312, 1313, and 1314. Each of the plurality of transport vehicles 1301, 1302, 1303, and 1304 may correspond to the transport vehicle 100 and each of the plurality of drones 1311, 1312, 1313, and 1314 may correspond to the drone 200.

As shown, the data center switches 1018 and 1019 are connected to the transport vehicle control system servers 1011 and 1021. The data center switches 1028 and 1029 are connected to the drone control system servers 1012 and 1022.

Each of the transport vehicle wireless controller 1110 and the drone wireless controller 1120 is connected to the core switches 1108 and 1109 and controls communication within the semiconductor manufacturing factory FAB.

The core switch 1108 is connected to the data center switches 1018 and 1029, while the core switch 1109 is connected to the data center switches 1018 and 1029.

Each of the plurality of AP switches 1218, 1219, 1228, and 1229 is connected to core switches 1108 and 1109.

Each of the plurality of transport vehicles 1301, 1302, 1303, and 1304 is connected to the plurality of AP switches 1218 and 1219. Each of the plurality of drones 1311, 1312, 1313, and 1314 is connected to the plurality of AP switches 1228 and 1229.

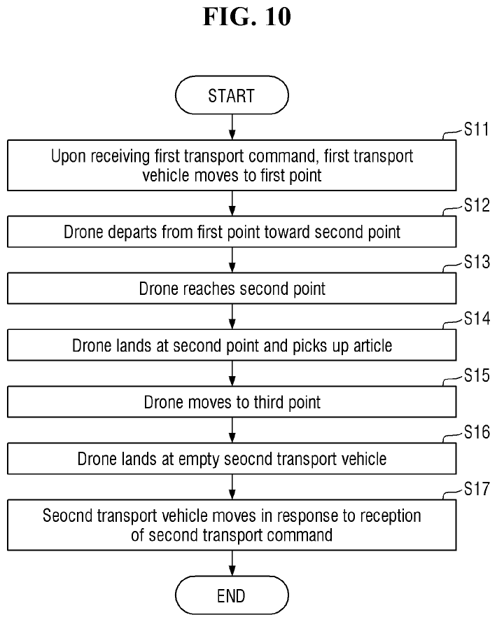

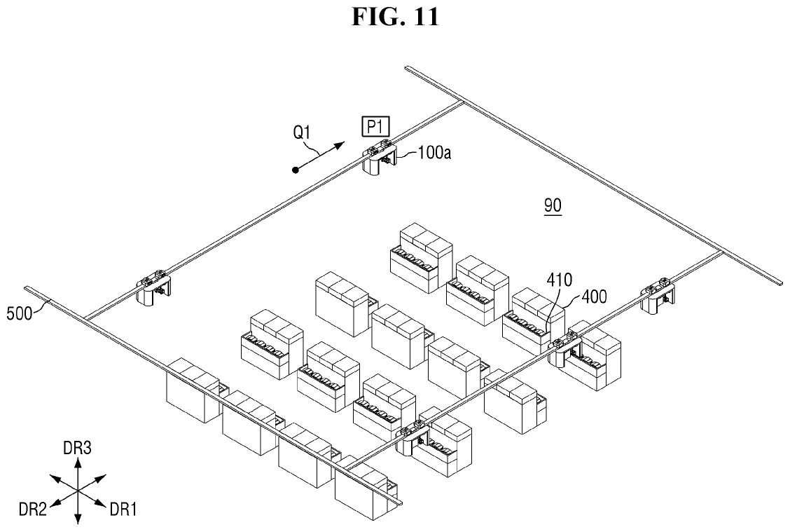

FIG. 10 is a flowchart for illustrating a method for operating the transport system according to one or more embodiments. FIG. 11 to FIG. 17 are diagrams of intermediate steps of the method of FIG. 10.

Referring to FIG. 10 and FIG. 11, upon receiving the first transport command, a first transport vehicle 100a moves to a first point P1 in S11.

Specifically, the higher-level control system provides a first transport command to the first transport vehicle 100a and/or the drone 200.

Based on the first transport command, the first transport vehicle 100a moves to the first point P1 when the drone 200 is seated thereon (refer to Q1 in FIG. 11). In this regard, the first point P1 is not a point where the article 9 is picked up (for example, a manufacturing facility or stocker), but is a point away from the point where the article 9 is picked up. For example, the first point P1 may be positioned not inside the bay 90 but around the bay 90.

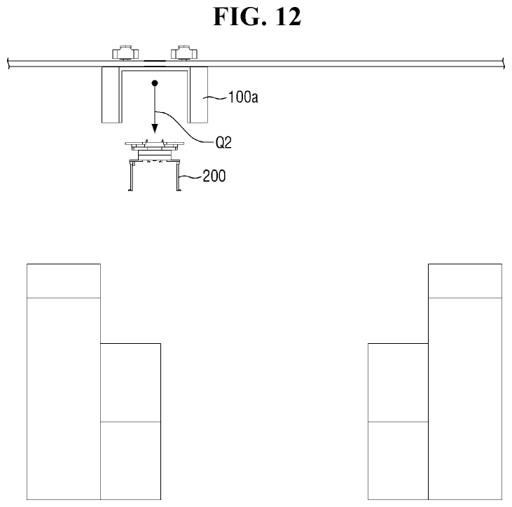

Referring to FIG. 10 and FIG. 12, the drone 200 starts flying at the first point P1 in S12.

Specifically, the drone 200 is removed from the first transport vehicle 100a at the first point P1 and begins flight, which is shown as “Q2” in FIG. 12. For example, when the propeller of the drone 200 starts to rotate to reach a preset speed, the support structure 130 (e.g., the first support structure 131 and the second support structure 132 in FIG. 4) of transport vehicle 100a opens. In other words, as the area between the first support structure 131 and the second support structure 132 widens, the drone 200 may fly and move.

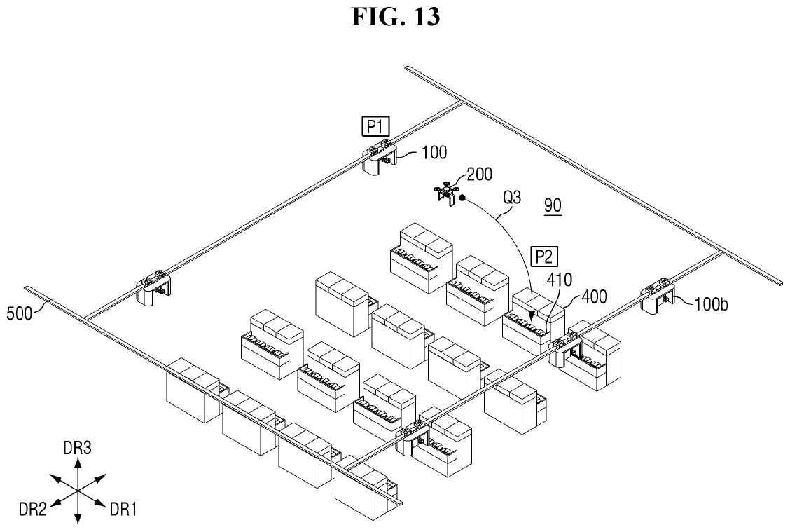

Referring to FIG. 10 and FIG. 13, the drone 200 flies and moves to a second point P2 in S13.

Specifically, the drone 200 moves to the second point P2, which is shown as “Q3” in FIG. 13. The second point P2 is a point where the article 9 is picked up. For example, the second point P2 may be the load port 410 of the manufacturing facility 400 or the stocker including a plurality of storage areas.

For example, the plurality of manufacturing facilities 400 are arranged in a first row and a second row disposed on both opposing sides of the passage, and the rail 500 is not installed on top of the passage. Therefore, the drone 200 flies from a position out of the passage and reaches one of the manufacturing facilities 400 arranged in the first row or the second row.

Thus, the rail 500 is installed in an area away from the plurality of manufacturing facilities 400, that is, outside the bay 90. The rail 500 does not need to have a position tag corresponding to each of the plurality of manufacturing facility 400 installed thereon. Therefore, there is no need for the operator to perform the high-risk task of adjusting a position of the position tag at a high level position.

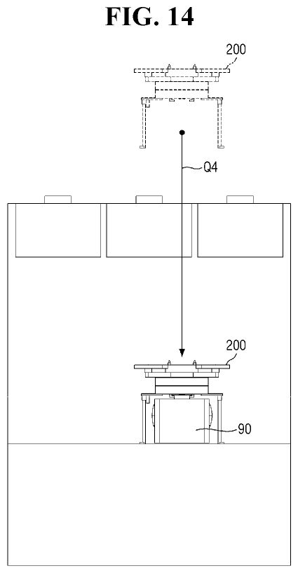

Referring to FIG. 10 and FIG. 14, the drone 200 lands at the second point P2 and picks up the article 9 in S14.

Specifically, as shown, the drone 200 descends vertically at the second point P2, shown as “Q4” in FIG. 14. In other words, drone 200 lands on the load port of the manufacturing facility. Next, the drone 200 communicates with the PIO sensor of the manufacturing facility using the PIO sensor 262 (in FIG. 7), and reads the information tag of the manufacturing facility using the reader 265 (in FIG. 7) to check the port information of the manufacturing facility, and check whether the drone is seated at the correct position. After checking the port information and whether the drone is seated at the correct position, the drone 200 picks up the article 9.

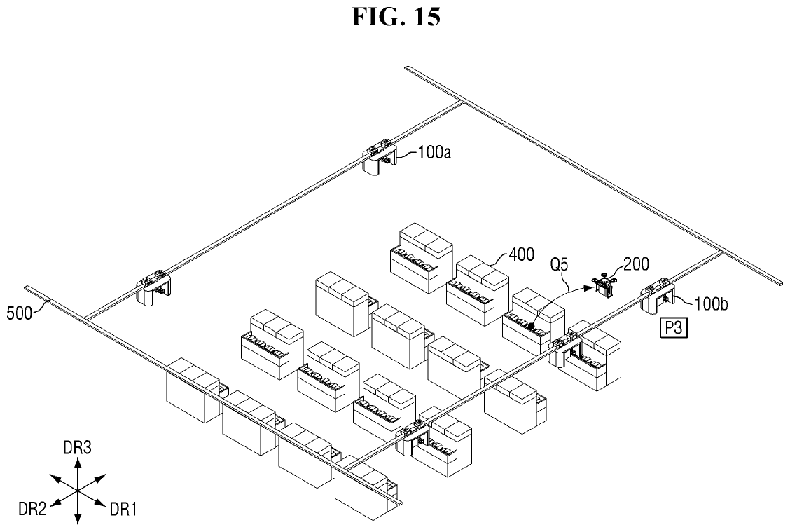

Referring to FIG. 10 and FIG. 15, the drone 200 flies and moves to a third point P3 in S15.

In this regard, the drone 200 moves to the third point P3, shown as “Q5” in FIG. 15. In an embodiment, the third point P3 may be in a different position from the first point P1. For example, when the first point P1 is one side (for example, a left side) around the bay 90, the third point P3 may be the other side (for example, a right side) around the bay 90.

The drone 200 communicates with a second transport vehicle 100b on which a drone is not mounted. The drone 200 may move to the third point P3 to board the second transport vehicle 100b.

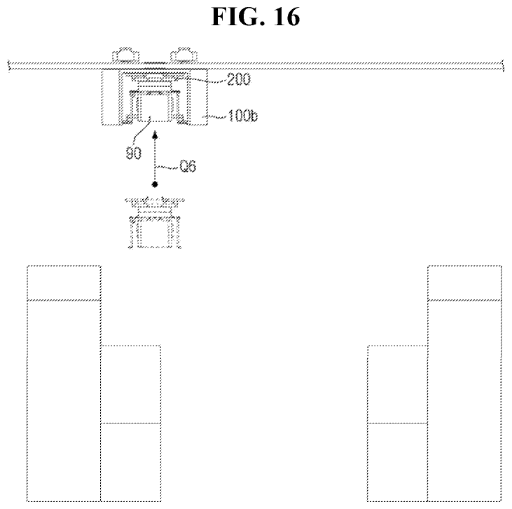

Referring to FIG. 10 and FIG. 16, the drone 200 docks at the second transport vehicle 100b in S16.

Specifically, the drone 200 flies and moves to an inner area of the second transport vehicle 100b, which is shown as “Q6” in FIG. 16. Next, the position pin 280 (in FIG. 6) of the drone 200 and the position hole of the second transport vehicle 100b are engaged with each other, so that the drone 200 is positioned at the correct position within the second transport vehicle 100b.

Subsequently, the supporter (the first support structure 131 and the second support structure 132 in FIG. 4) of the second transport vehicle 100b is closed. That is, as the area between the first support structure 131 and the second support structure 132 narrows, the second transport vehicle 100b is fixed by the first support structure 131 and the second support structure 132 (or the anti-drop members). Next, the drone 200 stops rotating the propeller.

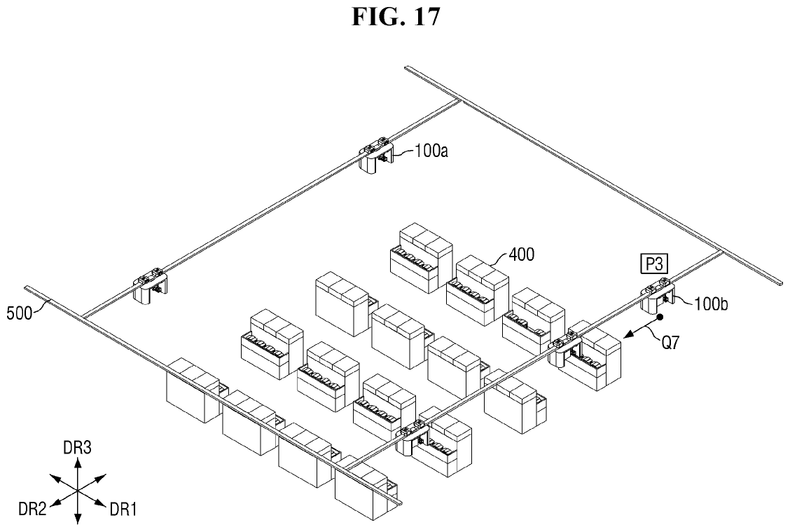

Referring to FIG. 10 and FIG. 17, the second transport vehicle 100b (on which the drone 200 has been seated) receives a second transport command and moves in response thereto in S17.

Specifically, the higher-level control system provides the second transport command to the second transport vehicle 100b on which the drone 200 is seated. The second transport vehicle 100b moves in response to the second transport command, which is shown as “Q7” in FIG. 17.

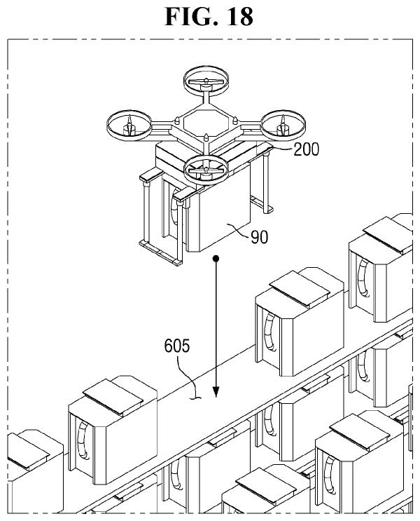

FIG. 18 is a diagram for illustrating a method for operating a transport system according to one or more embodiments. The following descriptions mainly focus on differences thereof from those set forth above using FIG. 10 to FIG. 17.

The article pickup point as described in FIG. 10 to FIG. 17 is in the manufacturing facility. Alternatively, an article pickup point to be described in FIG. 18 may be the stocker 600 including a plurality of storage areas 605. The drone 200 may pick up the article 9 directly from the storage area 605 of the stocker 600, or place the article 9 directly into the storage area 605. Therefore, a size of the storage area 605 is required to be large enough for the drone 200 to be seated therein. However, because the drone 200 directly picks up or puts down the article 9, the stocker 600 does not require a separate robot, such as a crane, for loading and unloading the article 9.

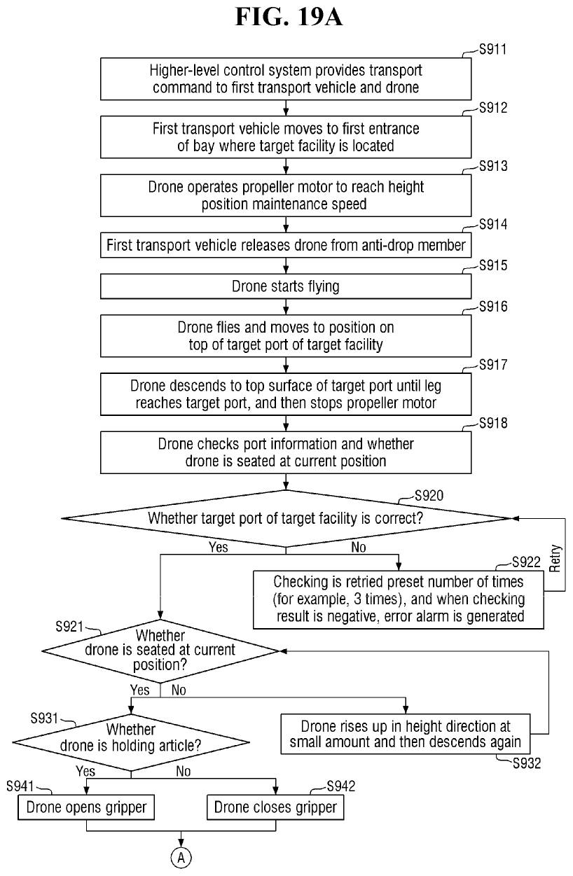

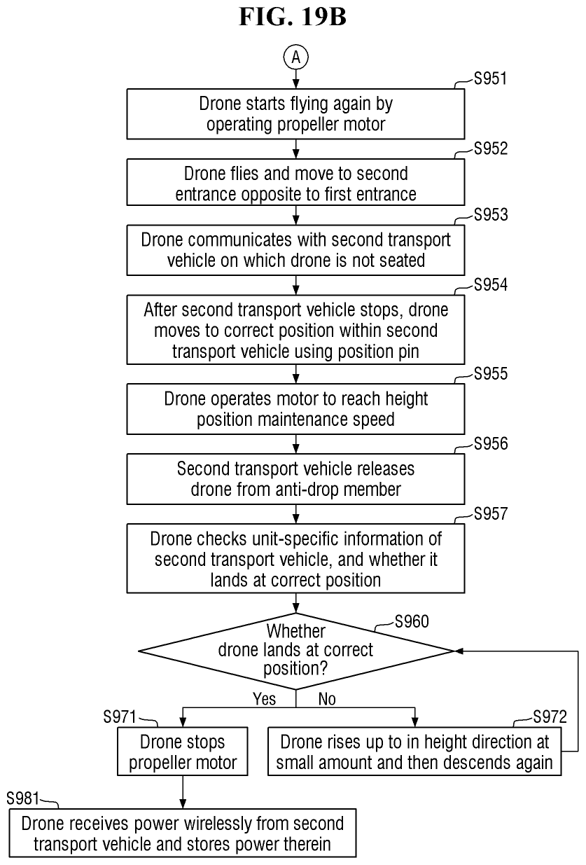

FIGS. 19A and 19B are a flowchart for illustrating a method for operating a transport system according to one or more embodiments. The following descriptions mainly focus on differences thereof from those set forth above using FIG. 10 to FIG. 17.

Referring to FIGS. 19A and 19B, the higher-level control system provides a transport command to the first transport vehicle 100a and the drone 200 in S911.

Subsequently, the first transport vehicle 100a moves to a first entrance of the bay where a target facility is located in S912.

Next, the drone 200 operates the propeller motor to reach a height position maintenance speed in S913. In this regard, the height position maintenance speed refers to a speed at which the drone 200 may be maintained at a preset height position within the first transport vehicle.

Subsequently, the first transport vehicle 100a releases the drone 200 from the anti-drop member in S914.

Next, the drone 200 starts flying in S915.

Next, the drone 200 flies and moves to a position on top of a target port of the target facility in S916.

Next, the drone 200 descends to a top surface of the target port until the leg 260 reaches the target port, and then stops the propeller motor in S917.

Next, the drone 200 checks the port information and whether the drone 200 is seated at the current position in S918.

In response to that the target port of the target facility is correct (Yes in S920), whether the drone is seated at the current position is checked in S921.

In response to that the drone is seated at the current position is checked (Yes in S921), whether the drone 200 is holding the article 9 is checked in S931.

In response to that the drone 200 is holding the article 9 (Yes in S931), the drone 200 opens the gripper 230 and puts down the article 9 in S941.

In response that the drone 200 is not holding the article 9 (No in S931), the drone 200 closes the gripper 230 and picks up the article 9 on the target port in S942.

Otherwise, in response to that the target port of the target facility is incorrect (No in S920), the checking is retried a preset number of times (for example, 3 times). Further, when the checking result is negative, an error alarm is generated in S922.

In response to that the drone 200 is not seated at the current position (No in S921), the drone 200 rises up in a height direction at a small amount and then descends again in S932. Thereafter, the drone 200 checks again whether the drone 200 lands at the correct position in S921.

After S941 and S942 are performed, the drone 200 starts flying again by operating the propeller motor in S951.

Next, the drone 200 flies and move to a second entrance opposite to the first entrance in S952.

Subsequently, the drone communicates with the second transport vehicle 100b on which a drone 200 is not seated in S953.

Subsequently, after the second transport vehicle 100b stops, the drone 200 moves to the correct position within the second transport vehicle 100b using the position pin 280 in S954.

Next, the drone 200 operates the motor to reach a height position maintenance speed in S955.

Subsequently, the second transport vehicle 100b releases the drone 200 from the anti-drop member in S956.

Next, the drone 200 checks unit-specific information of the second transport vehicle 100b, and whether the drone 200 lands at the correct position in S957.

Next, whether the drone 200 lands at the correct position in S960.

In response to that the drone 200 lands at the correct position (Yes in S960), the drone 200 stops the propeller motor in S971.

Subsequently, the drone receives power wirelessly from the second transport vehicle 100b and stores the power therein in S981.

Otherwise, in response to that the drone 200 lands at an incorrect position (No in S960), the drone rises up to in the height direction at a small amount and then descends again in S972. Then, the drone 200 checks whether it lands at the correct position again in S960.

Embodiments of the disclosure have been described with reference to the accompanying drawings. The embodiments of the disclosure may be implemented in various different forms. A person skilled in the art may appreciate that the disclosure may be practiced in other concrete forms without changing the technical spirit or essential characteristics of the disclosure. Therefore, the embodiments as described above are not restrictive but illustrative in all respects.

What is claimed is:

1. A transport vehicle comprising:
a frame having an internal area;
a driver on top of the frame, the driver being configured to travel along a rail;
a support structure in the internal area, the support structure being configured to seat, thereon, a drone configured to transport an article; and
a controller configured to control an operation of at least one of the driver and the support structure.

2. The transport vehicle of claim 1, wherein the support structure comprises:
a first support plate,
a second support plate facing the first support plate, and
a driving component configured to adjust an area between the first support plate and the second support plate.

3. The transport vehicle of claim 2, further comprising an anti-drop member at the support structure, the anti-drop member being configured to prevent the drone seated on the support structure from falling down,
wherein the anti-drop member comprises:
a first rod connected to the first support plate, the first rod being configured to protrude beyond a first edge of the first support plate; and
a second rod connected to the second support plate, the second rod being configured to protrude beyond a second edge of the second support plate, and
wherein the first rod and the second rod move as the first support plate and the second support plate move, respectively.

4. The transport vehicle of claim 1, wherein the frame comprises a position hole, and
wherein the position hole is engaged with a position pin of the drone to determine a position of the drone.

5. The transport vehicle of claim 1, further comprising a wireless power supply in the internal area, the wireless power supply being configured to supply power to the drone during at least a portion of a period during which the drone is seated on the support structure.

6. The transport vehicle of claim 1, wherein the drone comprises:
a body;
a wing assembly connected to the body, the wing assembly being configured to generate a lift force to fly the drone;
a gripper connected to the body, the gripper being configured to grip the article; and
a leg connected to the body, the leg being configured to support the body when the drone is seated on the support structure.

7. The transport vehicle of claim 6, wherein the drone further comprises:
a wireless charging pad configured to receive power from a wireless power supply in the frame; and
a battery connected to the wireless charging pad, the battery being configured to store the power received from the wireless power supply.

8. The transport vehicle of claim 6, wherein the drone further comprises a reader on the leg, the reader being configured to read an information tag on a load port or the support structure.

9. The transport vehicle of claim 6, wherein the drone further comprises a position pin on an upper surface of the wing assembly, and
wherein the position pin is configured to guide the drone to be seated at a position in the internal area.

10. A transport vehicle comprising:
a frame having an internal area;
a driver on top of the frame, the driver being configured to move along a rail;
a support structure in the internal area, the support structure being configured to seat, thereon, a drone configured to transport an article; and
an anti-drop member at the support structure, the anti-drop member being configured to prevent the drone seated on the support structure from falling down; and
a wireless power supply in the frame, the wireless power supply being configured to supply power to the drone during at least a portion of a period during which the drone is seated on the support structure,
wherein the drone comprises:
a body;
a wing assembly connected to the body, the wing assembly being configured to generate a lift force to fly the drone;
a gripper connected to the body, the gripper being configured to grip the article;
a leg connected to the body, the leg being configured to support the body when the drone is seated on the support structure;
a wireless charging pad installed on the wing assembly, the wireless charging pad being configured to receive the power from the wireless power supply;
a battery connected to the wireless charging pad, the battery being configured to store the power received from the wireless power supply; and
a reader on the leg, the reader being configured to read an information tag on a load port or the support structure.

11. The transport vehicle of claim 10, further comprising:
a position hole inside the frame; and
a position pin on an upper surface of the wing assembly of the drone, the position pin being engaged with the position hole to guide the drone to be seated at a position in the internal area.

12. A transport system comprising:
a rail;
a first transport vehicle configured to move along the rail; and
a drone configured to be seated on the first transport vehicle, move to a first point, be removed from the first transport vehicle at the first point, and fly to a second point, and pick up an article at the second point,
wherein the first transport vehicle comprises:
a frame having an internal area;
a driver on top of the frame, the driver being configured to move along the rail;
a support structure in the internal area, the support structure being configured to seat the drone thereon; and
a controller configured to control an operation of at least one of the driver or the support structure.

13. The transport system of claim 12, wherein the drone is further configured to pick up the article at the second point, fly to a third point, and be seated on a second transport vehicle at the third point.

14. The transport system of claim 12, wherein the second point is a load port of a manufacturing facility,
wherein a plurality of manufacturing facilities are arranged in a first row and a second row respectively disposed on both opposing sides of a passage, wherein the rail is not installed in the passage, and
wherein the drone is further configured to fly from a position out of the passage and reach one of the plurality of manufacturing facilities in the first row or the second row.

15. The transport system of claim 12, wherein the second point is a load port of a manufacturing facility,
wherein a plurality of manufacturing facilities are arranged in a first row and a second row respectively disposed on both opposing sides of a passage, wherein the rail is installed in the passage, and
wherein a position tag corresponding to each of the plurality of manufacturing facilities is not installed on the rail.

16. The transport system of claim 12, wherein the second point is a stocker comprising a plurality of storage areas,
wherein the stocker excludes a separate robot for loading and unloading the article, and
wherein the drone is further configured to pick up the article from one of the plurality of storage areas.

17. The transport system of claim 12, wherein the drone comprises a reader on a leg of the drone, and
wherein the drone is further configured to read information tag at the second point using the reader.

18. The transport system of claim 12, wherein the drone is further configured to receive power wirelessly from the first transport vehicle when being seated on the first transport vehicle.

19. The transport system of claim 12, wherein the drone comprises:
a body;
a wing assembly connected to the body, the wing assembly being configured to generate a lift force to fly the drone;
a gripper connected to the body, the gripper being configured to grip the article; and
a leg connected to the body, the leg being configured to support the body when the drone is seated on the support structure.

20. The transport system of claim 19, wherein the first transport vehicle comprises an anti-drop member at the support structure, the anti-drop member being configured to prevent the drone seated on the support structure from falling down,
wherein, before the first transport vehicle reaches the first point, the drone is further configured to start to rotate a propeller of the wing assembly, and
wherein, when the anti-drop member releases the drone, the drone is further configured to start to fly.
